(19) United States
(12) Patent Application Publication
(10) Pub. No.: US 2026/0059892 A1
(43) Pub. Date: Feb. 26, 2026

(54) SHORT-RANGE OPTICAL POTENTIOMETER MODULE

(71) Applicant: GUANGDONG RUIXUN ELECTRONIC TECHNOLOGY CO., LTD., Guangdong (CN)

(72) Inventors: Aihua CHEN, Guangdong (CN); Mingyong TANG, Guangdong (CN); Jianping LI, Guangdong (CN); Guangnan ZHU, Guangdong (CN); Jie XIANG, Guangdong (CN)

(21) Appl. No.: 18/850,081

(22) PCT Filed: Oct. 31, 2023
(86) PCT No.: PCT/CN2023/128343

§ 371 Date: Apr. 24, 2025

(30) Foreign Application Priority Data
Nov. 15, 2022 (CN) 202211426545.X

(51) Int. Cl. H10F 55/20

(52) U.S. Cl. CPC H10F 55/208; H10F 55/207

(57) ABSTRACT

Disclosed in the present invention is a short-range optical potentiometer module, comprising a potential base body provided with a key slot, and a potential key which is mounted inside the key slot and can be displaced up and down, wherein a reset member for resetting the potential key is also arranged inside the key slot, an optical pair transistor composed of a photosensitive element and a light-emitting element is arranged inside the potential key, the optical pair transistor can be displaced up and down along with the potential key, a key base is internally provided with a fixed grating corresponding to the optical pair transistor, the reset member is sleeved on the grating, and the grating is configured such that the flux of light received by the photosensitive element from the light-emitting element changes along with the up-and-down displacement of the potential key, thereby causing an electrical signal generated by the photosensitive element to change along with the displacement of the potential key. The module of the solution uses non-contact photoelectric elements, thereby greatly increasing the service life; when the change in flux of light at the same distance is adjusted, the overall height of the module is close to or the same as the height of a potential base body; and the module has a skillful overall structure layout, can be conveniently assembled and replaced, and has strong practicality.

### TECHNICAL FIELD

The present invention relates to a potentiometer module, and specifically relates to a short-range optical potentiometer module.

### BACKGROUND OF THE INVENTION

Commonly used potentiometer elements control different currents using different resistance values so as to adjust potential values. For example, games in computers often use a joystick for control. In a general joystick structure, there is an external control lever that can be gripped and swung by hand, and during operation, movement via the control lever is converted into an electronic signal, which is received by a game interface card and then input into a computer host to control movement of a cursor.

This type of potentiometers, apart from seriously affecting the service life of the variable resistor or potentiometer, is also unable to provide a very accurate resistance value; even friction phenomenon between a folding motion and carbon resistance arranged by a sliding lever may also make electronic equipment to produce a very large clutter, so it is popular in the electronics industry to use an optical potentiometer instead, which has higher sensitivity and is suitable for mass production; optical potentiometer is a technology that uses a grating element in cooperation with an optical element to convert an optical signal into an electric signal for output. In another solution of the present inventor in the same period of time (not the prior art of the present patent), a novel optoelectronic potentiometer module with a potential key and a potential base body is designed, in which solution a grating is arranged on the potential key that can be moved up and down, while an optical pair transistor is fixed and immovable. Because the grating is of certain length, when the potentiometer module is not pressed, the overall module height (i.e., the height from the top of the potential key to the bottom of the potential base body when the potentiometer module is not pressed) will be higher, equivalent to the height of the potential base body plus the length of the grating. However, in some applications, it is necessary to reduce the module height of the potentiometer, and the present invention is sharply developed based on this, i.e., another novel short-range (i.e., shortening the distance between the top of the potential key and the bottom of the potential base body when it is not pressed) potentiometer module easy to manufacture and assemble.

### BRIEF SUMMARY OF THE INVENTION

Regarding the above problem, the present invention aims to provide an optical potentiometer module capable of greatly shortening distance between the top of a potential key and the bottom of a potential base body without being pressed.

In order to achieve this technical purpose, the solution of the present invention is a short-range optical potentiometer module, comprising a potential base body provided with a key slot, and a potential key which is mounted inside the key slot and can be displaced up and down, wherein a reset member for resetting the potential key is also arranged inside the key slot, an optical pair transistor composed of a photosensitive element and a light-emitting element is arranged inside the potential key, the optical pair transistor can be displaced up and down along with the potential key; a key base is internally provided with a fixed grating corresponding to the optical pair transistor, and the reset member is sleeved on the grating which is configured such that the flux of light received by the photosensitive element from the light-emitting element changes along with the up-and-down displacement of the potential key, thereby causing an electrical signal generated by the photosensitive element to change with the displacement change of the potential key.

Preferably, the grating is a shaft base with a gradual light through-hole protruding in the key base, the potential key is configured with a guide slot relative to the shaft base, the gradual light through-hole corresponds to light path of the optical pair transistor, and when the potential key is pressed to produce a displacement change, an opening area of the gradual light through-hole corresponding to the light path also changes accordingly, enabling the flux of light received by the photosensitive element from the light-emitting element to also change accordingly.

Preferably, the potential key is also provided with a baffle plate extending on an inner wall, which baffle plate is located between the light-emitting element and the photosensitive element, the light path on the baffle plate corresponding to the light-emitting element and the photosensitive element being provided with a light-transmitting hole.

Preferably, the light pair transistor is mounted on a flexible circuit board provided with a U-shaped head, a slot member of the U-shaped head matches with the guide slot to ensure that the U-shaped head is able to move up and down through the shaft base, and the light-emitting element and the photosensitive element are located on both sides of the U-shaped head.

Preferably, the potential key is also detachably mounted with a cover body.

Preferably, the U-shaped head is provided with assembly positioning holes, the cover body is provided with a positioning slot at the bottom corresponding to the assembly positioning holes, the potential key is provided with positioning columns, the U-shaped head of the flexible circuit board is mounted on the positioning columns of the potential key through the assembly positioning holes, and the cover body is mounted on the positioning columns of the potential key through the positioning slot.

Preferably, both the potential key and the potential base body are provided on sides with through-holes, through which the flexible circuit board can pass.

Preferably, the potential key is provided with four bottom columns in four corners at the bottom, and the base is provided with four evacuation slots corresponding to the bottom columns.

Preferably, the shaft base is composed of two pieces of shaft columns having sloping surfaces and arranged in opposite to each other, the sloping surfaces of the two pieces of shaft columns being staggered from each other to form a gradual light through-hole of a V-shaped structure.

The beneficial effect of the present invention is that: the optical potentiometer of the present scheme adopts an optical pair transistor in combination with a potential key to change the flux of light to achieve output of the changing electrical signal, the formed signal is stable, reliable and sensitive, and the module adopts a non-contact photoelectric element to greatly prolong the service life; in particular, when adjusting the change in the flux of light at the same distance in the form of fixing the grating and moving the optical pair transistor, the overall height of the module is close to or the same as the height of the potential base body; the flux of light is changed through the gradual light through-hole, whereby the photosensitive element outputs a gradual linear potentiometric signal; further, the optical pair transistor is designed as an independent body easy to plug and play relative to the potential key and the potential base body, which structure is extremely easy to assemble, maintain and replace; the overall structure of the module is skillfully laid out, easy to assemble and replace, and thus it is highly useful and has enormous market potential.

### BRIEF DESCRIPTION OF THE DRAWINGS

FIG. 1 is a schematic diagram of the structure of the present invention.

FIG. 2 is a schematic diagram of the pressed structure of the present invention.

FIG. 3 is an exploded view of the present invention.

FIG. 4 is a schematic diagram of the structure of a potential key in the present invention.

FIG. 5 is a schematic diagram of the structure of the potential base body in the present invention.

FIG. 6 is a schematic diagram of the internal structure of the present invention.

FIG. 7 is a schematic diagram of the structure of the potential key and the flexible circuit board in the present invention.

FIG. 8 is a schematic diagram of the structure of the flexible circuit board in the present application.

FIG. 9 is a schematic diagram of the pressing of a moving grating and a fixed optical pair transistor.

FIG. 10 is a schematic diagram of the pressing of a moving optical pair transistor and a fixed grating in the present invention.

1, potential base body; 11, key slot; 12, shaft base; 13, gradual light through-hole; 14, evacuation slot; 2, potential key; 21, guide slot; 22, baffle plate; 220, light-transmitting hole; 23, positioning column; 24, bottom column; 3, reset spring; 4, light-emitting element; 5, photosensitive element; 6, flexible circuit board; 61, U-shaped head; 610, slot member; 611, assembly positioning hole; 7, cover body; 71, positioning slot; 8, through-hole.

### DETAILED DESCRIPTION OF THE INVENTION

Further detailed description is set forth below in connection with the appended drawings and the specific embodiments for the present invention. In order to clearly and completely illustrate the technical solutions, the following embodiments are selected for illustration. The following embodiments are part of the embodiments of the present invention; based on the present application, other embodiments obtained without creative labor are all within the scope of protection of the present invention.

In the following embodiments, it is noted that the terms ‘up’, ‘down’, ‘left’, ‘right’, ‘inside’, “outside”, “top/bottom” and other orientations or positional relationships are all based on those shown in the accompanying drawings, and are intended only to facilitate a clear description of the present embodiment, not indicating or implying that the device or component referred to is required to be in a particular position. Thus, they should not be construed as a limitation to the present application. At the same time, ‘first’ and ‘second’ in the embodiments are used only for the purpose of distinguishing the illustration, and are not meant to indicate or imply relative importance.

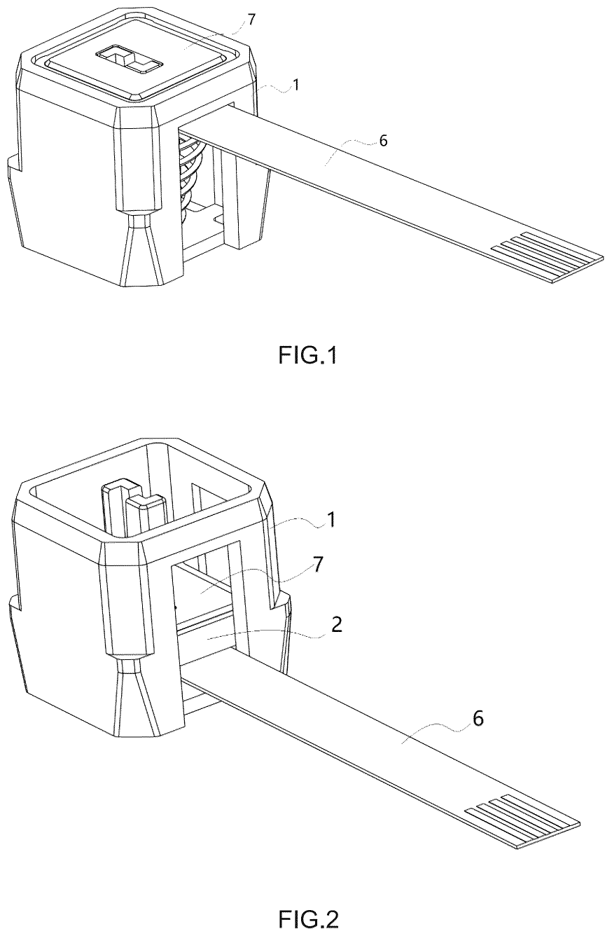

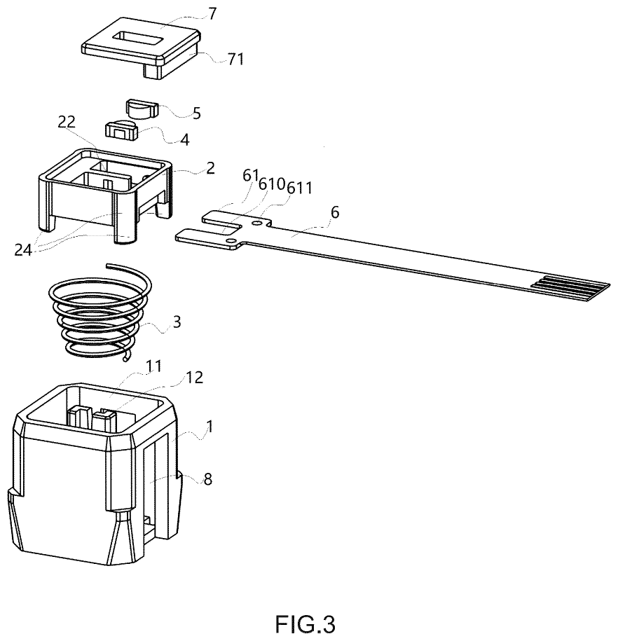

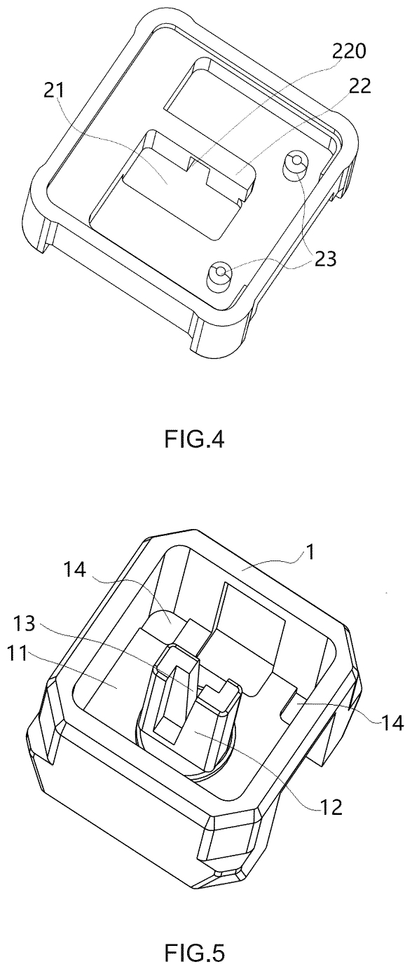

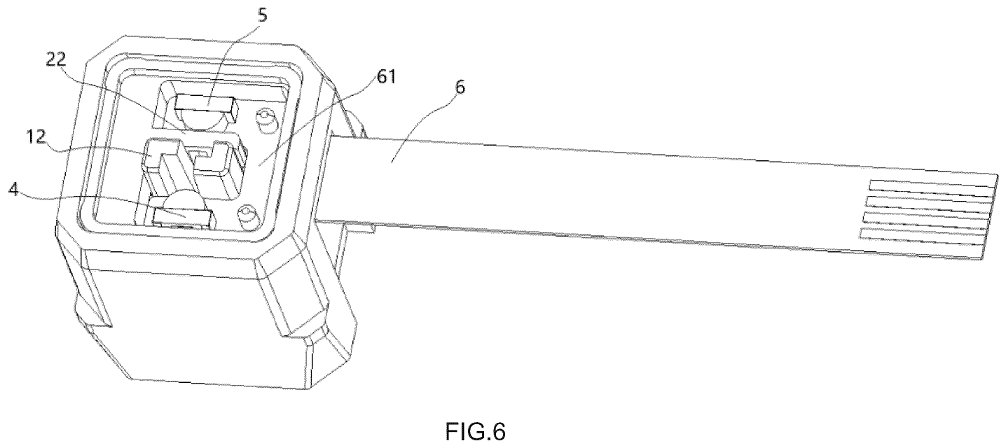

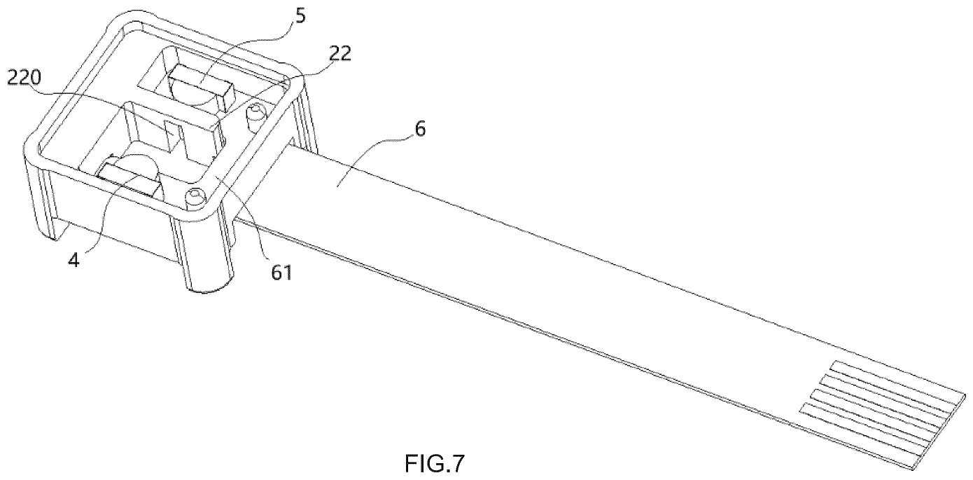

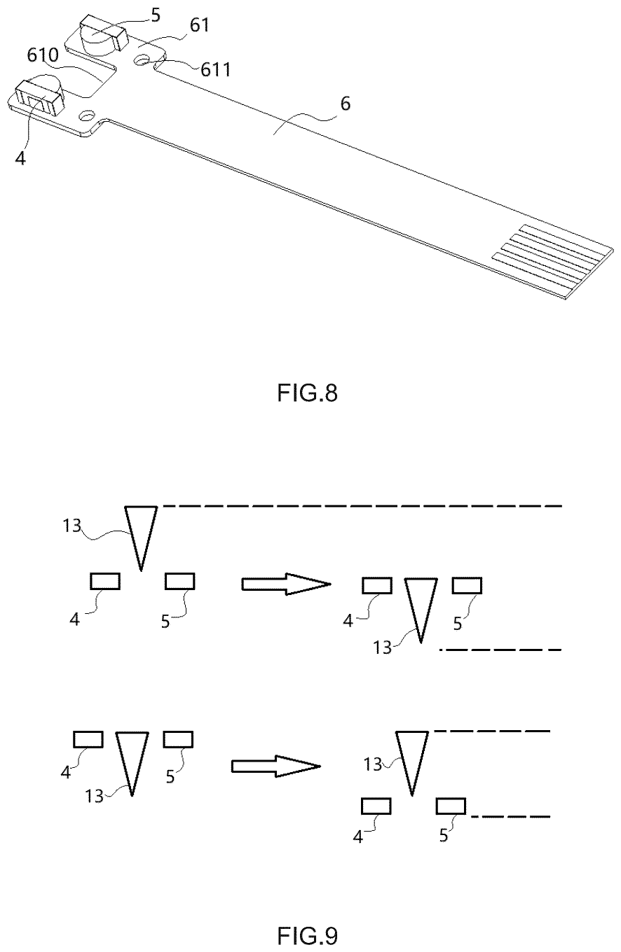

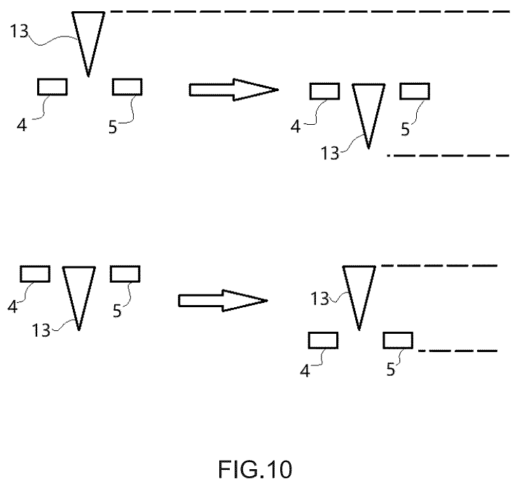

As shown in FIGS. 1-8, a specific embodiment of the present invention is a short-range optical potentiometer module, comprising a potential base body 1 provided with a key slot 11, and a potential key 2 which is mounted inside the key slot 11 and can be displaced up and down, a reset member for resetting the potential key 2 being also arranged inside the key slot 11, an optical pair transistor composed of a photosensitive element 5 and a light-emitting element 4 is arranged inside the potential key 2, the optical pair transistor can be displaced up and down along with the potential key 2; a key base is internally provided with a fixed grating corresponding to the optical pair transistor, and the reset member of the present application is preferably a reset spring 3 sleeved on the grating, the top of the reset spring 3 is abutted to the bottom of the potential key 2, and the grating is configured such that the flux of light received by the photosensitive element 5 from the light-emitting component 4 changes along with the up-and-down displacement of the potential key 2, thereby causing an electrical signal generated by the photosensitive element 5 to change along with the displacement change of the potential key 2. The grating of the present application is fixed inside the potential base body 1, and the optical pair transistor is constructed inside the potential key 2 to move up and down with the potential key 2. When the optical pair transistor moves through the grating, different photoelectric signals are produced by adjustment of the grating. The benefit of this change is that in order to bring about change in the flux of light over a sufficient distance, the grating is generally longer than the optical pair transistor, and thus as shown in FIGS. 9-10, when adjusting the change in the flux of light at the same distance, the height of the module in FIG. 10 can be significantly reduced compared to the manner in FIG. 9, so that the overall height of the module is close to or the same as the height of the potential base body.

In specific Embodiment 1 of the present application, the grating is a shaft base 12 with a gradual light through-hole 13 protruding in the key base, the potential key 2 is configured with a guide slot 21 relative to the shaft base 12, the gradual light through-hole 13 corresponds to light path of the optical pair transistor, and when the potential key 2 is pressed to produce a displacement change, an opening area of the gradual light through-hole 13 corresponding to the light path also changes accordingly, enabling the flux of light received by the photosensitive element 5 from the light-emitting element 4 to also change accordingly.

The potential key 2 is also provided with a baffle plate 22 extending on an inner wall, which baffle plate 22 is located between the light-emitting element 4 and the photosensitive element 5, the light path on the baffle plate 22 corresponding to the light-emitting element 4 and the photosensitive element 5 being provided with a light-transmitting hole 220. When there is no obstruction, light pulse radiated by the light-emitting element 4 is received by the photosensitive element 5 through the light-transmitting hole 220, and the present application also has a shaft base 12 for adjusting flux of light, which is provided with a gradual light through-hole 13, and the light-transmitting hole 220 corresponds to the gradual light through-hole 13. When pressing the potential key 2, the flux of light received by the photosensitive element 5 from the light-emitting element 4 is subjected to adjustment by the gradual light through-hole 13 to produce a change, thereby outputting different potentiometric signals.

The light pair transistor is mounted on a flexible circuit board 6 provided with a U-shaped head, a slot member 610 of the U-shaped head matches with 2 guide slot 21 to ensure that the U-shaped head is able to move up and down through the shaft base 12, the light-emitting element 4 and the photosensitive element 5 are located on both sides of the U-shaped head, the light-emitting element 4 and the photosensitive element 5 are located on both sides of the shaft base 12, and the optical pair transistor can be adjusted by the shaft base 12 when moving up and down following the potential key 2.

In order to facilitate pressing, the potential key 2 is also detachably mounted with a cover body 7, which also plays the role of dust and light protection.

The U-shaped head has assembly positioning holes 611, the cover body 7 is provided at the bottom with a positioning slot 71 corresponding to the assembly positioning holes 611, the potential key 2 is provided with positioning columns 23, the U-shaped head of the flexible circuit board 6 is mounted on the positioning columns 23 of the potential key 2 through the assembly positioning holes 611, and the cover body 7 is mounted on the positioning columns 23 of the potential key 2 through the positioning slot 71.

When assembling, both the potential key 2 and the potential base body 1 are provided on the sides with through-holes 8, through which the flexible circuit board 6 can pass. After the U-shaped head of the flexible circuit board 6 is fixed to the potential key 2, its tail passes through the through-holes 8 on the sides of the potential key 2 and the potential base body 1. In addition, at the time of designing, the potential key 2 is provided with four bottom columns 24 in four corners at the bottom such that there is enough space at the bottom of the potential key 2 for accommodating the reset spring 3, and the reset spring 3 is abutted to the bottom of the potential key 2 and located among the bottom columns 24, which is more stable, and the potential base body 1 is provided with four evacuation slots 14 corresponding to the bottom columns 24.

As specific Embodiment 2 of the present application, the shaft base 12 is composed of two pieces of shaft columns having sloping surfaces and arranged in opposite to each other, the sloping surfaces of the two pieces of shaft columns being staggered from each other to form a gradual light through-hole 13 of a V-shaped structure. Correspondingly, when the optical pair transistor is located on the top of the V-shaped structure, the flux of light through the light-transmitting hole 220 received by the photosensitive element 5 is relatively large, and during the process of gradually pressing, through the bottom of the V-shaped structure, the flux of light through the light-transmitting hole 220 received by the photosensitive element 5 is gradually smaller, and the output potentiometric signals produce a linear change.

As specific Embodiment 3 of the present application, the shaft base 12 is composed of two pieces of shaft columns having stepped surfaces and arranged in opposite to each other, the stepped surfaces can be designed as upward or downward steps, and the stepped surfaces of the two shaft columns are staggered from each other, so that when the optical pair transistor moves along with the potential key 2, the flux of light received by the photosensitive element 5 and the potentiometric signal output from the flexible circuit board 6 both change accordingly when passing through the stepped surfaces.

As specific Embodiment 4 of the present application, the shaft base 12 is composed of two pieces of shaft columns having curved surfaces and arranged in opposite to each other, the curved surfaces of the two pieces of shaft columns are staggered from each other, so that when the optical pair transistor moves along with the potential key 2, the flux of light received by the photosensitive element 5 and the potentiometric signal output from the flexible circuit board 6 both change accordingly when passing through the stepped surfaces.

It should be emphasized that the reason why the grating in the scheme of the present invention adopts the aforesaid shaft columns arranged in opposite is to facilitate the design of the injection mould. If the grating is designed by using the closed frame structure, it is almost impossible to produce an injection-moulded potential base body 1. Therefore, the present invention adopts this kind of structures to solve the technical problem effectively, so as to make the mould design and manufacturing cost lower and make the realization credible.

Besides, it should be noted that the potentiometer module of the present invention is not a keyboard key, and it is not the user's finger that presses the potential key in the potentiometer module, but a mechanical structural member, and the potentiometer module can be used in general for the gamepad, joystick, or other fields that need to output continuously changing electrical signals, which is nothing but common knowledge of persons skilled in the art.

The foregoing is only a preferred embodiment of the present invention, and is not intended to limit the present invention, and any minor modifications, equivalent replacements and improvements made to the above embodiments based on the technical substance of the present invention shall be included in the scope of protection of the technical solution of the present invention.

1. A short-range optical potentiometer module, comprising a potential base body provided with a key slot, and a potential key which is mounted inside the key slot and can be displaced up and down, a reset member for resetting the potential key being also arranged inside the key slot, wherein an optical pair transistor composed of a photosensitive element and a light-emitting element is arranged inside the potential key, the optical pair transistor can be displaced up and down along with the potential key; a key base is internally provided with a fixed grating corresponding to the optical pair transistor, and the reset member is sleeved on the grating which is configured such that the flux of light received by the photosensitive element from the light-emitting element changes along with the up-and-down displacement of the potential key, thereby causing an electrical signal generated by the photosensitive element to change along with the displacement of the potential key.

2. The short-range optical potentiometer module according to claim 1, wherein the grating is a shaft base with a gradual light through-hole protruding in the key base, the potential key is configured with a guide slot relative to the shaft base, the gradual light through-hole corresponds to light path of the optical pair transistor, and when the potential key is pressed to produce a displacement change, an opening area of the gradual light through-hole corresponding to the light path also changes accordingly, enabling the flux of light received by the photosensitive element from the light-emitting element also to change accordingly.

3. The short-range optical potentiometer module according to claim 2, wherein the potential key is also provided with a baffle plate extending on an inner wall, which baffle plate is located between the light-emitting element and the photosensitive element, the light path on the baffle plate corresponding to the light-emitting element and the photosensitive element being provided with a light-transmitting hole.

4. The short-range optical potentiometer module according to claim 3, wherein the light pair transistor is mounted on a flexible circuit board provided with a U-shaped head, a slot member of the U-shaped head matches with the guide slot to ensure that the U-shaped head is able to move up and down through the shaft base, and the light-emitting element and the photosensitive element are located on both sides of the U-shaped head.

5. The short-range optical potentiometer module according to claim 4, wherein the potential key is also detachably mounted with a cover body.

6. The short-range optical potentiometer module according to claim 5, wherein the U-shaped head is provided with assembly positioning holes, the cover body is provided with a positioning slot at the bottom corresponding to the assembly positioning holes, the potential key is provided with positioning columns, the U-shaped head of the flexible circuit board is mounted on the positioning columns of the potential key through the assembly positioning holes, and the cover body is mounted on the positioning columns of the potential key through the positioning slot.

7. The short-range optical potentiometer module according to claim 5, wherein both the potential key and the potential base body are provided on sides with through-holes, through which the flexible circuit board can pass.

8. The short-range optical potentiometer module according to claim 5, wherein the potential key is provided with four bottom columns in four corners at the bottom, and the base is provided with four evacuation slots corresponding to the bottom columns.

9. The short-range optical potentiometer module according to any one of claims 2-8, wherein the shaft base is composed of two pieces of shaft columns having sloping surfaces and arranged in opposite to each other, the sloping surfaces of the two pieces of shaft columns being staggered from each other to form a gradual light through-hole of a V-shaped structure.
